(19) United States
(12) Patent Application Publication
(10) Pub. No.: US 2004/0266116 A1
(43) Pub. Date: Dec. 30, 2004

(54) METHODS OF FABRICATING SEMICONDUCTOR STRUCTURES HAVING IMPROVED CONDUCTIVITY EFFECTIVE MASS

(75) Inventors: Robert J. Mears, Wellesley, MA (US); Jean Augustin Chan Sow Fook Yiptong, Waltham, MA (US); Marek Hytha, Brookline, MA (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: RJ Mears, LLC, Waltham, MA

(21) Appl. No.: 10/603,621

(22) Filed: Jun. 26, 2003

(51) Int. Cl. H01L 21/336

(52) U.S. Cl. 438/285

(57) ABSTRACT

The present invention relates to controlling the properties of semiconductor materials at the atomic or molecular level to achieve improved performance within semiconductor devices. Further, the invention relates to the identification, creation, and use of improved materials for use in the conduction paths of semiconductor devices. More specifically, the inventors have identified materials or structures having energy band structures in which the average curvature of the conduction and valence bands and band edges is substantially greater than the average curvature of conduction and valence bands in single crystal silicon. This substantially greater curvature corresponds to lower effective mass and, hence, greater carrier mobility. The disclosed semiconductor structures have one or more atomic layers of an (non-semiconductor) element or compound other than a semiconductor which are interposed between layers of a semiconductor to increase the average curvature of the valence and conduction bands and improve the carrier mobility of the semiconductor structure.

### CROSS-REFERENCE TO RELATED APPLICATIONS

None.

### STATEMENT REGARDING FEDERALLY SPONSORED RESEARCH OR DEVELOPMENT

Not applicable.

### BACKGROUND OF THE INVENTION

1. Field of the Invention

The present invention relates broadly to semiconductor structures and devices in which one or more atomic layers of an element or compound other than a semiconductor are interposed between layers of a semiconductor in order to reduce the conductivity effective mass of electrons and/or holes, with a view to improving the carrier mobility of semiconductor structure.

2. Description of the Related Art

It is well known in the semiconductor art that for parabolic bands the second derivative, or curvature, of a valence band maximum and conduction band minimum, d²E/dk², is inversely proportional to the effective mass. Thus, higher curvature gives a lower effective mass. It is also well known that the carrier transport properties of semiconductors are very sensitive to the effective mass and that, in general, small effective mass is related to high carrier mobility. In practice, the precise relationship between effective mass and carrier mobility is dependent on various scattering mechanisms, doping, electric field, etc., but it is generally understood that the premium on low effective mass in semiconductor materials is high, even under the extreme transport conditions that exist in modern high field (deep) sub-micron MOSFETs.

Many methods and structures have been used or proposed for improving the operational performance of semiconductor devices. One such method has been to create strain in layers of Si, Ge, or SiGe to alter the carrier mobility in those layers.

One such technique is disclosed in published U.S. Patent Application No. 20030057416. The published application discloses a technique which, in a simplified form, provides a silicon substrate, deposits a relaxed graded SiGe buffer layer to a final Ge composition on the silicon substrate, deposits a relaxed SiGe cap layer having a uniform composition on the graded SiGe buffer layer, planarizes the SiGe cap layer, deposits a relaxed SiGe regrowth layer having a uniform composition, and deposits a strained silicon layer on the SiGe regrowth layer. The lattice constant of SiGe is larger than that of Si and is a direct function of the amount of Ge in the SiGe alloy. The graded SiGe buffer layer, which is epitaxially deposited, initially is strained to match the in-plane lattice constant of the underlying silicon substrate. The deposition of the relaxed graded SiGe buffer layer enables engineering of the lattice constant of the SiGe cap layer and, therefore, the amount of strain in the strained silicon layer.

### SUMMARY OF THE INVENTION

The present invention provides semiconductor structures and devices having more desirable effective mass, and hence carrier mobility through the formation of atomic layers of a semiconductor such as silicon and materials other than the semiconductor to create a structure in which atomic layers of materials other than the semiconductor are interposed between atomic layers of the semiconductor. One such material other than a semiconductor is oxygen. Semiconductor materials other than silicon, such as Ge, SiGe, GaAs, SiC, InP, InAs, GaP or related ternary or quaternary alloys and other semiconductor materials may be used. Likewise, materials other than oxygen, such as nitrogen, fluorine, CO or other inorganic or organic elements or compounds which are compatible with a given semiconductor fabrication process may be used.

The anisotropic nature of semiconductor materials means that quantities such as effective mass are tensorial in nature rather than scalar quantities. Thus, the direction of fields and carrier transport are an integral feature of the observed carrier transport properties.

In order to discriminate between potential structures the inventors use the measure “inverse conductivity effective mass tensor”, which is defined below. The inverse of a component of this tensor corresponding to a preferred direction of transport is referred to as the “conductivity effective mass”.

The semiconductor structures of the present invention have conductivity effective masses for electrons and holes that are substantially different than the corresponding values for the base semiconductor.

The invention features a semiconductor structure having a first semiconductor layer having a plurality of atomic layers of a semiconductor; a first atomic layer of an (non-semiconductor) element or compound other than the semiconductor on the first semiconductor layer; a second semiconductor layer having a plurality of atomic layers of the semiconductor on the first atomic layer of an (non-semiconductor) element or compound other than the semiconductor; and a second atomic layer of the (non-semiconductor) element or compound other than the semiconductor on the second layer of the semiconductor.

In one embodiment, the invention provides a method of forming a semiconductor device having the steps of forming what one may refer to as a super silicon layer by forming a first plurality of atomic layers of silicon on a substrate, forming a first atomic layer of oxygen on the first plurality of atomic layers of silicon, and forming a second plurality of atomic layers of silicon on the atomic layer of oxygen, forming a second atomic layer of oxygen on the second plurality of atomic layers of silicon; forming at least one p-type region in or adjacent to the super silicon layer; forming at least one n-type region in or adjacent to the super silicon layer; and forming a plurality of electrodes.

The invention further provides a semiconductor structure having a first atomic layer of silicon; an atomic layer of oxygen on the first atomic layer of silicon; and a second atomic layer of silicon on the atomic layer of oxygen; wherein the semiconductor structure has conductivity effective masses for electrons and holes that are substantially less than the corresponding values for silicon.

Still other aspects, features, and advantages of the present invention are readily apparent from the following detailed description, simply by illustrating preferable embodiments and implementations. The present invention is also capable of other and different embodiments, and its several details can be modified in various respects, all without departing from the spirit and scope of the present invention. Accordingly, the drawings and descriptions are to be regarded as illustrative in nature, and not as restrictive.

### BRIEF DESCRIPTION OF THE DRAWINGS

The accompanying drawings, which are incorporated in and constitute a part of this specification illustrate some embodiments of the invention and, together with the description, serve to explain the objects, advantages, and principles of the invention. In the drawings,

FIG. 1 is a diagram of a typical planar MOSFET geometry.

FIG. 2 is a diagram of the 4-to-1 Silicon to Oxygen structure of a preferred embodiment of the invention.

FIGS. 3a-c are diagrams of the energy bands of the 4-to-1 Silicon to Oxygen structure of a preferred embodiment of the invention.

FIGS. 4a-h are diagrams showing various stages of fabrication of a semiconductor device.

### DETAILED DESCRIPTION OF THE PREFERRED EMBODIMENTS

The present invention relates to controlling the properties of semiconductor materials at the atomic or molecular level to achieve improved performance within semiconductor devices. Further, the invention relates to the identification, creation, and use of improved materials for use in the conduction paths of semiconductor devices.

Effective mass is described with various definitions in the literature. As a measure of the improvement in effective mass we use the “inverse conductivity mass tensor” that we define by:

$${M}_{e , i , j}^{- 1} ( {E}_{F} , T ) = {( \frac{1}{{m}_{e}} )}_{ij} = \frac{{\sum }_{{E}_{n} > {E}_{F}} {\int }_{B . Z} {( {∇}_{k} {E}_{n} ( k ) )}_{i} {( {∇}_{k} {E}_{n} ( k ) )}_{j} \frac{\partial f ( E ( k ) , {E}_{F} , T )}{\partial E} {ⅆ}^{3} k}{{\sum }_{{E}_{n} > {E}_{F}} {\int }_{B . Z .} f ( E ( k ) , {E}_{F} , T ) {ⅆ}^{3} k}$$

for electrons and:

$${M}_{h , i , j}^{- 1} ( {E}_{F} , T ) = {( \frac{1}{{m}_{h}} )}_{ij} = \frac{- {\sum }_{{E}_{n} > {E}_{F}} {\int }_{B . Z} {( {∇}_{k} {E}_{n} ( k ) )}_{i} {( {∇}_{k} {E}_{n} ( k ) )}_{j} \frac{\partial f ( E ( k ) , {E}_{F} , T )}{\partial E} {ⅆ}^{3} k}{{\sum }_{{E}_{n} > {E}_{F}} {\int }_{B . Z .} ( 1 - f ( E ( k ) , {E}_{F} , T ) ) {ⅆ}^{3} k}$$

for holes.

The inventors' definition of the inverse conductivity effective mass is such that a tensorial component of the conductivity of the material is greater for greater values of the corresponding component of the inverse conductivity mass tensor. In this patent application we will concentrate on setting the values of the inverse conductivity mass tensor so as to enhance the conductive properties of the material, typically for a preferred direction of carrier transport. The inverse of the appropriate tensor element we refer to as the conductivity effective mass.

In order to characterize semiconductor material structures, the invention relies on the conductivity effective mass for electrons/holes as described above and calculated in the direction of intended carrier transport as a means to distinguish improved materials.

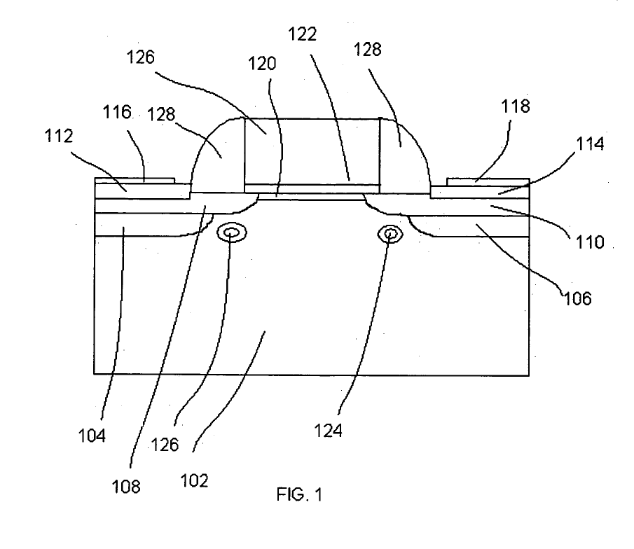

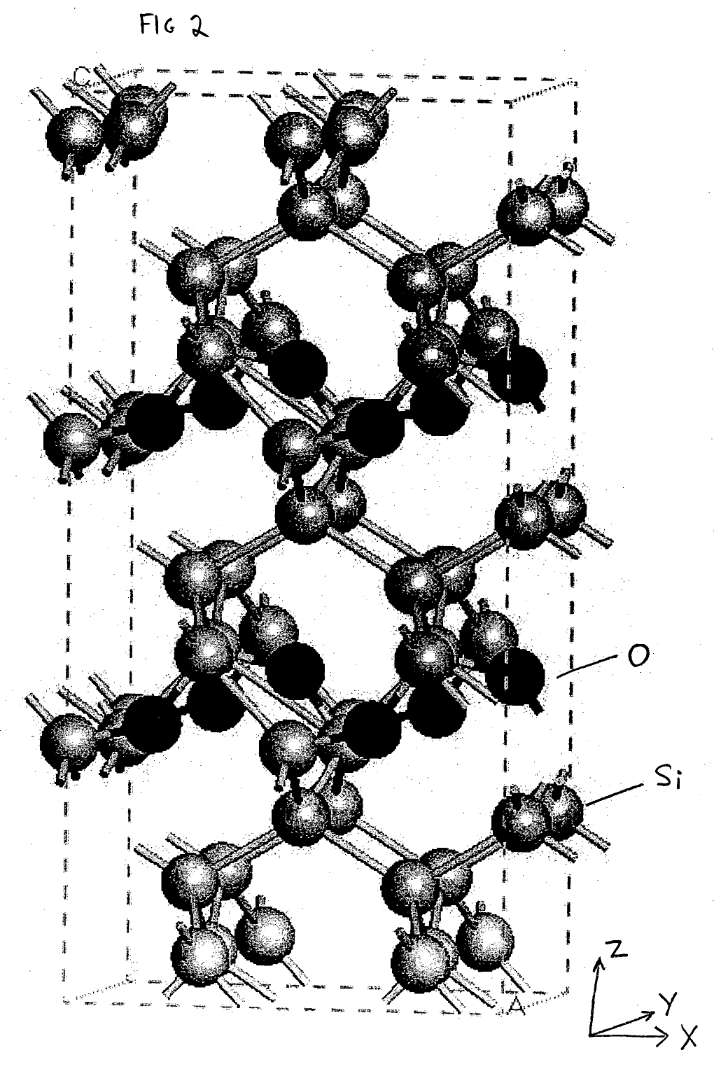

Using the above-described measures, one can select materials having improved band structures for specific purposes. One such example would be a material for a channel region in a CMOS device. For purposes of explanation, a typical planar MOSFET geometry is shown in FIG. 1. One skilled in the art, however, would know that the materials identified and discovered using the above methods could be used in many different types of integrated circuit devices.

As shown in FIG. 1, the typical planar MOSFET geometry includes a substrate 102, source/drain regions 104 and 106, source/drain extensions 108 and 110, source/drain silicides 112 and 114, source/drain contacts 116 and 118, halo implants 124 and 126, channel region 120, gate oxide 122, gate 126, and spacers 128. Using the above-described measures, the inventors have identified improved materials or structures for the channel region 120.

More specifically, the inventors have identified materials or structures having energy band structures for which the conductivity effective masses for electrons and holes that are substantially less than the corresponding values for silicon.

The materials or structures are controlled at the atomic or molecular level and may be formed using known techniques of atomic layer deposition. The structures comprise a repeating structure of a plurality of atomic layers of a semiconductor material and a single atomic layer of a material ((non-semiconductor) element or compound) other than the semiconductor material such as oxygen, nitrogen, fluorine, CO or other inorganic or organic elements or compounds which are compatible with the given semiconductor fabrication process. This structure may be repeated two times or many times or combinations formed with different interleaved layers/different materials to form a low conductivity effective mass (high mobility) semiconductor region.

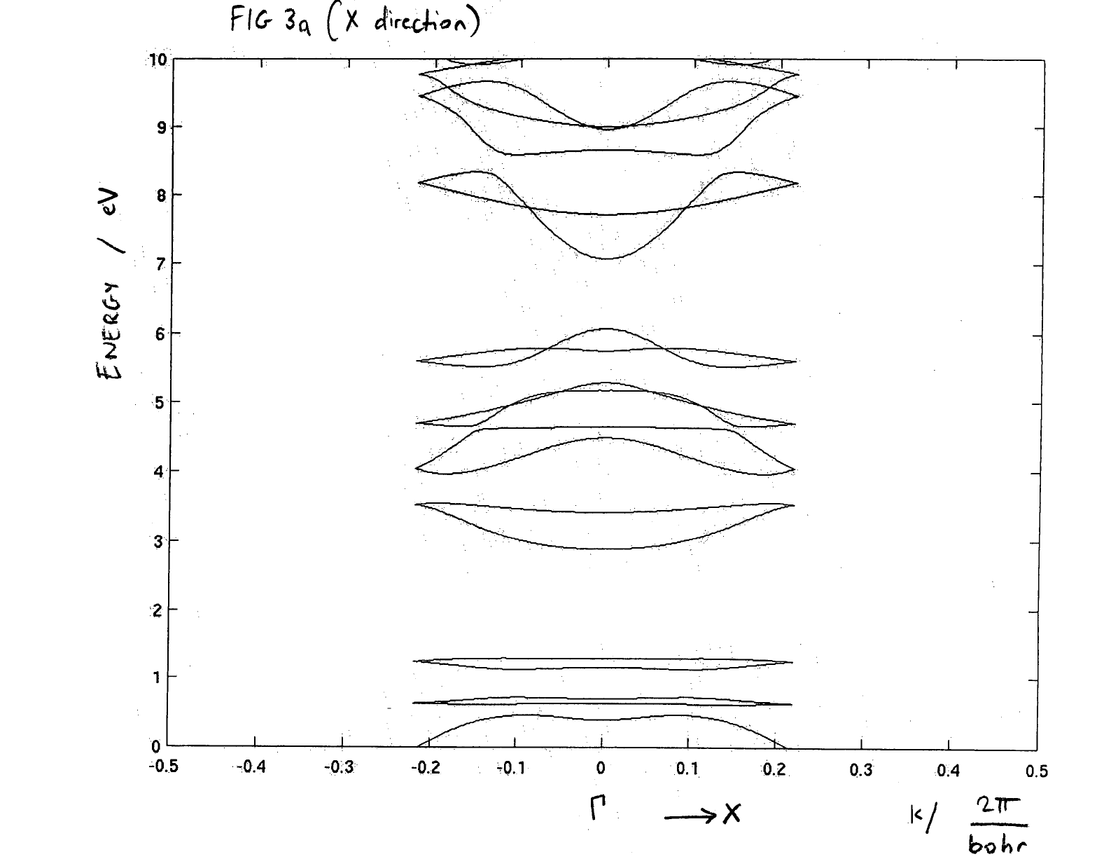

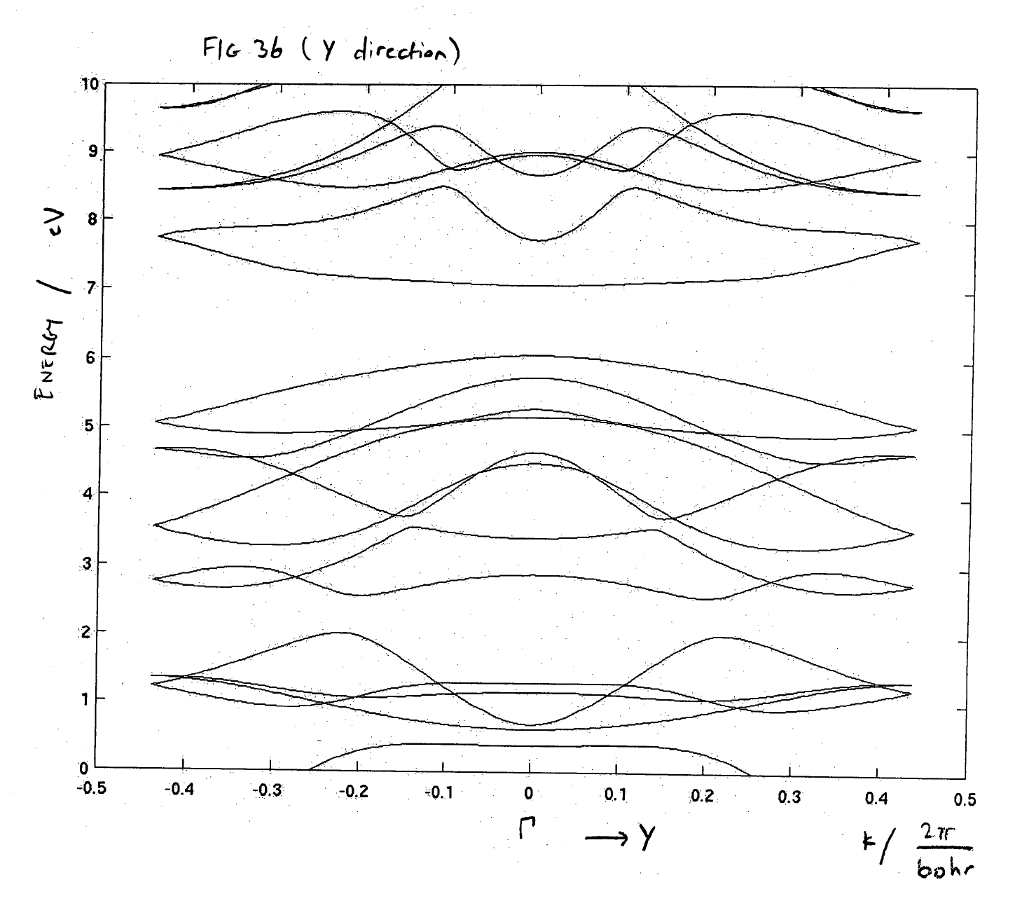

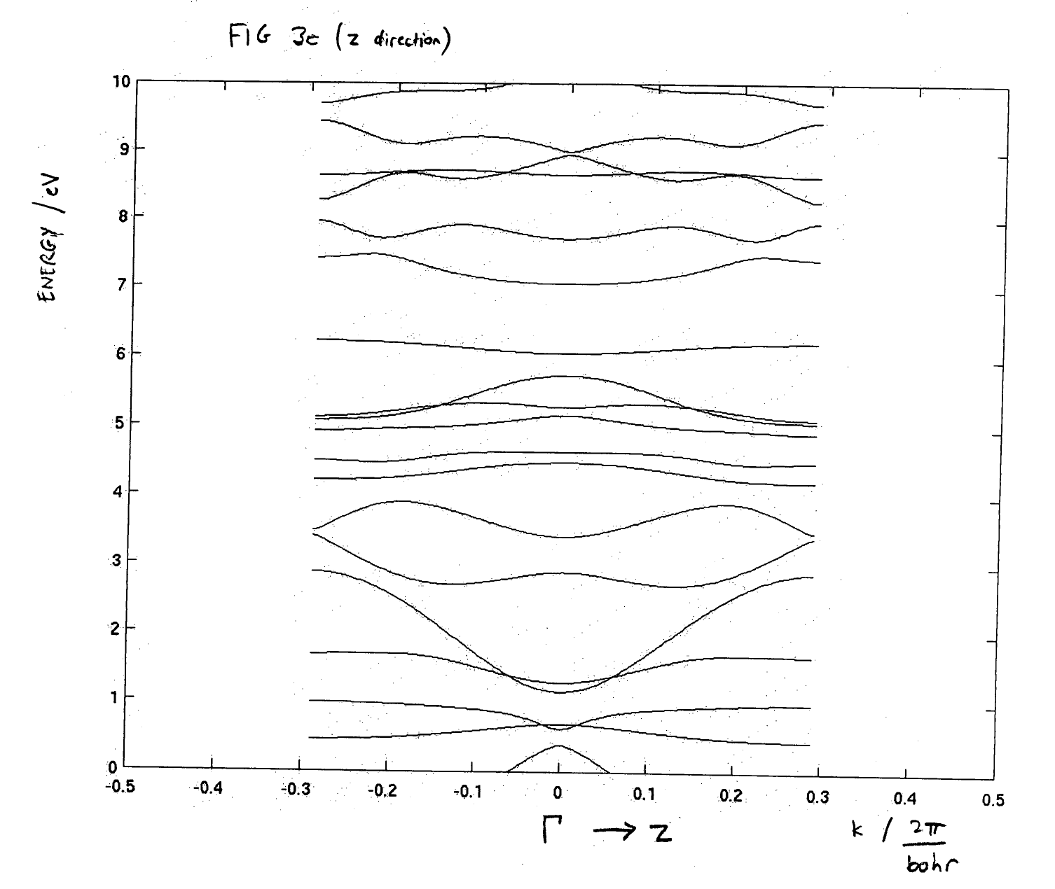

An example of one such structure is shown in FIG. 2. This example structure has a repeating structure of four atomic layers of silicon and a single atomic later of oxygen. This structure can be formed using known techniques of atomic layer deposition by, for example, forming a first atomic layer of silicon on a substrate, forming a second atomic layer of silicon on the first atomic layer, forming a third atomic layer of silicon on the second layer, forming a fourth atomic layer of silicon on the third layer, forming a fifth atomic layer of oxygen on the fourth layer, and then starting over by forming a sixth layer of silicon on the fifth layer of oxygen. This example structure results in the energy band structure shown in FIGS. 3a-c. This energy band structure of the present invention has conductivity effective masses for electrons and holes that are substantially less (less than half) than the corresponding values for silicon.

The above, of course, is only one example structure of the invention. Other structures can be formed using different non-semiconductor materials, such as nitrogen instead of oxygen, or a material from the list of nitrogen, fluorine, CO or other inorganic or organic elements or compounds which are compatible with the given semiconductor fabrication process, or using semiconductor material selected from a list of Group IV semiconductor (or IV-IV) such as Si, Ge or SiGe, SiC; Group III-V semiconductor such as GaAs, InP, In As, GaP and related ternary and quaternary alloys, GaN, GaSb and Group II-VI semiconductors such as CdS, CdSe etc. Also, different numbers of atomic layers of silicon or other material may be used, although it is preferable to use fewer than eight atomic layers of silicon.

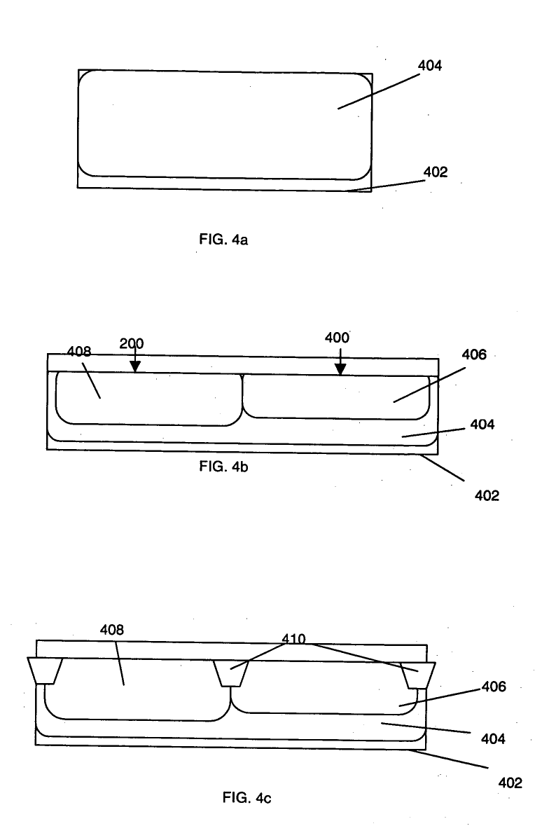

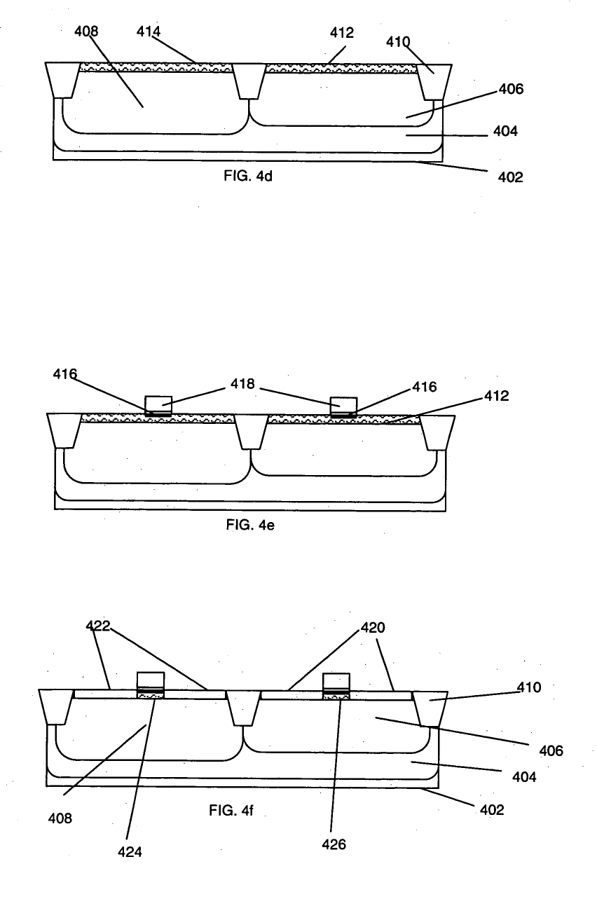

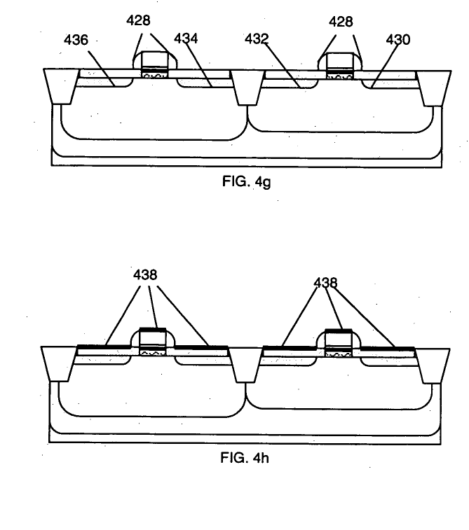

The invention would be one structure within a larger device. As an example, FIGS. 4a-h show how the formation of a channel region of the above structure would fit into a simplified CMOS fabrication process for manufacturing PMOS and NMOS transistors. The example process of FIGS. 4a-h begins with an eight inch wafer of lightly doped P-type or N-type single crystal silicon with <100> orientation 402. In the example, the formation of two transistors, one NMOS and one PMOS will be shown. In FIG. 4a, a deep N-well 404 is implanted in the substrate 402 for isolation. In FIG. 4b, N-well and P-well regions 406 and 408, respectively, are formed using an SiO₂/Si₃N₄ mask prepared using known techniques. This could entail, for example, steps of n-well and p-well implantation, strip, drive-in, clean, and re-growth. The strip step refers to removing the mask (in this case, photoresist and silicon nitride). The drive-in step is used to locate the dopants at the appropriate depth, assuming the implantation is lower energy (i.e. 80 keV) rather than higher energy (200-300 keV). A typical drive-in condition would be approximately 9-10 hrs. @ 1100-1150 C. The drive-in step also anneals out implantation damage. If the implant is of sufficient energy to put the ions at the correct depth then an anneal step follows, which is lower temperature and shorter. A clean step comes before any oxidation step so as to avoid contaminating the furnaces with organics, metals, etc. Other known ways or processes for reaching this point may be used as well.

In FIGS. 4c-h, and NMOS device will be shown in one side 200 of the Figures and a PMOS device will be shown in the other side 400 of the Figures. FIG. 4c depicts shallow trench isolation in which the wafer is patterned, the trenches 410 are etched (0.3-0.8 um), a thin oxide is grown, the trenches are filled with SiO₂, and then the surface is planarized. FIG. 4d depicts the definition and deposition of the semiconductor structures of the present invention as the channel regions 412, 414. An SiO₂ mask (not shown) is formed, a semiconductor structure of the present invention is deposited using atomic layer deposition, an epitaxial silicon cap layer is formed, and the surface is planarized to arrive at the structure of FIG. 4d. FIG. 4e depicts the devices after the gate oxide layers and the gates are formed. To form these layers, a thin gate oxide is deposited, and steps of poly deposition, patterning, and etching are performed. Poly deposition refers to low pressure chemical vapor deposition (LPCVD) of silicon onto an oxide (hence it forms a polycrystalline material). The step includes doping with P⁺ or As⁺ to make it conducting and the layer is around 250 nm thick. This step depends on the exact process, so the 250 nm thickness is only an example. The pattern step is made up of spinning photoresist, baking it, exposing it to light (photolithography step), and developing the resist. Usually, the patter is then transferred into another layer (oxide or nitride) which acts as an etch mask during the etch step. The etch step typically is a plasma etch (anisotropic, dry etch) that is material selective (e.g. etches silicon 10 times faster than oxide) and transfers the lithography pattern into the material of interest.

In FIG. 4f, lowly doped source and drain regions 420 and 422 are formed. These regions are formed using n-type and p-type LDD implantation, annealing, and cleaning. “LDD” refers to n-type lowly doped drain, or on the source side, p-type lowly doped source. This is a low energy/low dose implant that is the same ion type as the source/drain. An anneal step may be used after the LDD implantation, but depending on the specific process, it may be omitted. The clean step is a chemical etch to remove metals and organics prior to depositing an oxide layer.

FIG. 4g shows the spacer formation and the source and drain implants. An SiO₂ mask is deposited and etched back. N-type and p-type ion implantation is used to form the source and drain regions 430, 432, 434, and 436. Then the structure is annealed and cleaned. FIG. 4h depicts the self-aligned silicides formation, also known as salicidation. The salicidation process includes metal deposition (e.g. Ti), nitrogen annealing, metal etching, and a second annealing. This, of course, is just one example of a process and device in which the present invention may be used, and those of skill in the art will understand its application and use in many other processes and devices. In other processes and devices the structures of the present invention may be formed on a portion of a wafer or across substantially all of a wafer.

This, of course, is just one example of a process and device in which the present invention may be used, and those of skill in the art will understand its application and use in many other processes and devices. The invention is by no means limited to the process or structures of FIGS. 1 and 4a-l. In other processes and devices the structures of the present invention may be formed on a portion of a wafer or across substantially all of a wafer.

The foregoing description of the preferred embodiment of the invention has been presented for purposes of illustration and description. It is not intended to be exhaustive or to limit the invention to the precise form disclosed, and modifications and variations are possible in light of the above teachings or may be acquired from practice of the invention. The embodiment was chosen and described in order to explain the principles of the invention and its practical application to enable one skilled in the art to utilize the invention in various embodiments as are suited to the particular use contemplated. It is intended that the scope of the invention be defined by the claims appended hereto, and their equivalents. The entirety of each of the aforementioned documents is incorporated by reference herein.

What is claimed is:

1. A method of producing a semiconductor device comprising the steps of:
forming a semiconductor layer by
forming a first plurality of atomic layers of a semiconductor on a substrate;
forming a first atomic layer of a non-semiconductor on said plurality of atomic layers of a semiconductor;
forming a second plurality of atomic layers of a semiconductor on said atomic layer of said non-semiconductor; and
forming a second atomic layer of a non-semiconductor on said second plurality of atomic layers of a semiconductor;
forming at least one p-type region in or directly adjacent to said semiconductor layer;
forming at least one n-type region in or directly adjacent to said semiconductor layer; and
forming a plurality of electrodes.

2. A method according to claim 1 wherein said step of forming a first plurality of atomic layers of a semiconductor on a substrate comprises the step of forming a plurality of atomic layers of a silicon on a substrate.

3. A method according to claim 1 wherein said step of forming a first plurality of atomic layers of a semiconductor on a substrate comprises the step of forming fewer than eight atomic layers of said semiconductor on a substrate.

4. A method according to claim 1 wherein said step of forming a first plurality of atomic layers of a semiconductor on a substrate comprises the step of forming on a substrate a plurality of atomic layers of a semiconductor selected from the group of: Group IV semiconductors, Group VI semiconductors, Group II-V semiconductors, and Group II-VI semiconductors.

5. A method according to claim 1 wherein said step of forming a first plurality of atomic layers of a semiconductor on a substrate comprises the step of forming on a substrate a plurality of atomic layers of a semiconductor selected from the group of Si, Ge, SiGe, GaAs, InP, InAs, GaP, GaN, GaSb, CdS, and CdSe.

6. A method according to claim 1 wherein said step of forming a first atomic layer of a non-semiconductor on said plurality of atomic layers of a semiconductor comprises the step of forming a first atomic layer of oxygen on said plurality of atomic layers of a semiconductor.

7. A method according to claim 1 wherein said step of forming a first atomic layer of a non-semiconductor on said plurality of atomic layers of a semiconductor comprises the step of forming on said plurality of layers of a semiconductor a first atomic layer of one or more selected from the group of: oxygen, nitrogen, fluorine, and CO.

8. A method of forming a semiconductor structure comprising the steps of:
forming first, second, third and fourth atomic layers of silicon;
forming a fifth atomic layer of oxygen on said fourth atomic layer of silicon on a substrate; and
forming sixth, seventh, eighth, and ninth atomic layers of silicon on said fifth atomic layer of oxygen.
forming a tenth atomic layer of oxygen on said ninth atomic layer of silicon.

9. A method of forming a channel region comprising the steps of:
forming first, second, third and fourth atomic layers of silicon;
forming a fifth atomic layer of oxygen on said fourth atomic layer of silicon; and
forming sixth, seventh, eighth, and ninth atomic layers of silicon on said fifth atomic layer of oxygen.

10. A method of forming a high-conductivity region comprising the steps of:
forming a first plurality of atomic layers of a semiconductor on a substrate;
forming a first atomic layer of a non-semiconductor on said plurality of atomic layers of a semiconductor;
forming a second plurality of atomic layers of a semiconductor on said atomic layer of said non-semiconductor; and
forming a second atomic layer of a non-semiconductor on said second plurality of atomic layers of a semiconductor.

11. A method according to claim 9, wherein said high-conductivity region is a channel region.
